(19) United States
(12) Patent Application Publication
(10) Pub. No.: US 2025/0007212 A1
(43) Pub. Date: Jan. 2, 2025

(54) CONNECTOR AND TEST FIXTURE

(71) Applicant: JAPAN AVIATION ELECTRONICS INDUSTRY, LIMITED, Tokyo (JP)

(72) Inventors: Kentaro TODA, Tokyo (JP); Norihiro ANDOU, Tokyo (JP)

(73) Assignee: JAPAN AVIATION ELECTRONICS INDUSTRY, LIMITED, Tokyo (JP)

(21) Appl. No.: 18/668,142

(22) Filed: May 18, 2024

(30) Foreign Application Priority Data
Jun. 27, 2023 (JP) 2023-105171

(51) Int. Cl. H01R 13/627; G01R 31/69; H01R 12/72

(52) U.S. Cl. CPC H01R 13/6275; G01R 31/69; H01R 12/722

(57) ABSTRACT

A connector is mateable with a mating connector in a front-rear direction. The connector has a main portion which is formed of a multilayer wiring substrate. The multilayer wiring substrate includes a first metal conductive layer and a second metal conductive layer. The second metal conductive layer has two conductive exposed portions. The conductive exposed portions are exposed to an outside of the connector at opposite side surfaces, respectively, of the main portion. The conductive exposed portions correspond to hooks, respectively, of the mating connector. Each of the conductive exposed portions has a thickness greater than a thickness of a lock portion of the corresponding hook of the mating connector. The lock portion of each of the hooks is brought into contact with the corresponding conductive exposed portion when the lock portions lock a mated state where the mating connector and the connector are mated with each other.

### CROSS REFERENCE TO RELATED APPLICATIONS

This application is based on and claims priority under 35 U.S.C. § 119 to Japanese Patent Application No. JP2023-105171 filed Jun. 27, 2023, the contents of which are incorporated herein in their entirety by reference.

### BACKGROUND OF THE INVENTION

This invention relates to a connector which is mateable with a mating connector comprising two hooks.

Referring to FIG. 9, JP H07-221417 A (Patent Document 1) discloses a printed circuit board 900, or a connector 900, of this type. The connector 900 is mateable with a connector 950, or a mating connector 950, in an X-direction. The mating connector 950 has two hooks 952, buttons 954 and contact points, or mating contacts. The hooks 952 are provided at opposite side portions, respectively, of the mating connector 950 in a Y-direction. The hooks 952 are openable and closable by the buttons 954. The connector 900 is made of epoxy resin or the like. The connector 900 has a protruding plate 910. A distal end of the protruding plate 910 is provided with a pair of protruding portions 912 and contact portions 914, or contacts 914

Referring to FIGS. 9 and 10, an operation of mating the connector 900 with the mating connector 950 is achieved as described below. At first, a user presses the buttons 954 so that the hooks 952 change their state into an opened state. Next, the user attaches the mating connector 950 to the protruding plate 910 of the connector 900. Then, the connector 900 and the mating connector 950 change their state to a mated state where the connector 900 and the mating connector 950 are mated with each other. Thus, the mating contacts of the mating connector 950 are electrically connected with the contacts 914, respectively, of the connector 900. After that, the user stops pressing the buttons 954 so that the hooks 952 change their state into a closed state. Then, the hooks 952 catch on the protruding portions 912, respectively, and thereby the mated state of the connector 900 with the mating connector 950 is locked. Although the aforementioned mating connector 950 is configured so that the opening/closing operations of the hooks 952 are achieved by the buttons 954, Patent Document 1 also discloses a modified mating connector 950 that lacks the buttons 954 and that has hooks 952 which are openable and closable by their own resilience.

As described above, the printed circuit board 900, which is the connector 900, is made of epoxy resin or the like. Consider a case where the mating connector 950 has the hooks 952 which are made of material such as metal harder than the material of the printed circuit board 900. If a process including lock and unlock operations is repetitively performed under a mated state where the mating connector 950 in this case is mated with the printed circuit board 900, the printed circuit board 900 might be abraded to produce abrasion dust by the hooks 952 and degraded. Additionally, under the mated state, the abrasion dust might cause, for example, poor electrical continuity between the connector 900 and the mating connector 950 in this case. That is, reliability of electrical connection of the connector 900 and the mating connector 950 in this case might be reduced under the mated state. Consider another case where the modified mating connector 950 has the hooks 952 which are made of material such as metal harder than the material of the printed circuit board 900. If a process, which includes a mating of the modified mating connector 950 in this case with the printed circuit board 900 and a removal thereof therefrom, is repetitively performed, the hooks 952 are repeatedly slid on side surfaces, respectively, of the printed circuit board 900. The repeated sliding of the hooks 952 might cause further abrasion to the printed circuit board 900 and produce a great amount of abrasion dust. Thus, reliability of electrical connection of the connector 900 and the modified mating connector 950 in this case might be further reduced under a mated state where the modified mating connector 950 in this case is mated with the connector 900.

### SUMMARY OF THE INVENTION

It is an object of the present invention to provide a connector that has a structure which locks a mated state of a mating connector with the connector by using a hook of the mating connector and that can prevent production of abrasion dust upon a mating of the mating connector with the connector.

One aspect (first aspect) of the present invention provides a first connector mateable with a mating connector in a front-rear direction. The mating connector comprises two hooks and a mating contact. The hooks are positioned away from each other in a lateral direction perpendicular to the front-rear direction. Each of the hooks extends in the front-rear direction. Each of the hooks has a lock portion. The lock portion faces inward in the lateral direction. The first connector has a main portion which has a tongue-like shape. The main portion has opposite side surfaces in the lateral direction. The hooks correspond to the opposite side surfaces, respectively, of the main portion. The main portion is formed of a multilayer wiring substrate. The multilayer wiring substrate includes a first metal conductive layer and a second metal conductive layer. The first metal conductive layer and the second metal conductive layer are insulated from each other. The main portion comprises a plurality of contacts. Each of the contacts is formed on the first metal conductive layer. Each of the contacts is, at least in part, exposed to an outside of the first connector. The contact is contactable with the mating contact in an up-down direction perpendicular to both the front-rear direction and the lateral direction. The second metal conductive layer has two conductive exposed portions. The conductive exposed portions are exposed to the outside of the first connector at the opposite side surfaces, respectively, of the main portion. The conductive exposed portions correspond to the hooks, respectively. Each of the conductive exposed portions has a thickness greater than a thickness of the lock portion of the corresponding hook of the mating connector. The lock portion of each of the hooks is brought into contact with the corresponding conductive exposed portion when the lock portions lock a mated state where the mating connector and the first connector are mated with each other.

Another aspect (second aspect) of the present invention provides a second connector which is the first connector of the first aspect and further comprises features described below. Each of the hooks is made of metal. The second metal conductive layer is a ground layer. The lock portion of each of the hooks is electrically connected with the corresponding conductive exposed portion under the mated state.

Still another aspect (third aspect) of the present invention provides a test fixture for evaluating transmission characteristics of the mating connector. The test fixture comprises the second connector of the second aspect.

The connector of the present invention is configures as follows: the second metal conductive layer of the multilayer wiring substrate has the two conductive exposed portions; the conductive exposed portions are exposed to the outside of the connector at the opposite side surfaces, respectively, of the main portion; each of the conductive exposed portions has the thickness greater than the thickness of the lock portion of the corresponding hook of the mating connector; and the lock portion of each of the hooks is brought into contact with the corresponding conductive exposed portion when the lock portions lock the mated state where the mating connector and the connector are mated with each other. Accordingly, as compared to the connector 900 of Patent Document 1, the connector of the present invention prevents abrasion of the multilayer wiring substrate of the connector and production of abrasion dust upon the mating of the mating connector with the connector. Thus, the connector of the present invention avoids reduction of reliability of electrical connection of the connector and the mating connector by the production of the abrasion dust.

An appreciation of the objectives of the present invention and a more complete understanding of its structure may be had by studying the following description of the preferred embodiment and by referring to the accompanying drawings.

### BRIEF DESCRIPTION OF THE DRAWINGS

FIG. 1 is a perspective view showing a test fixture according to an embodiment of the present invention. In the figure, a mating connector is only partially shown, and a part of the test fixture is enlarged and illustrated.

FIG. 2 is a top view showing the test fixture of FIG. 1. In the figure, a part of the test fixture is enlarged and illustrated.

FIG. 3 is a partially cutaway, perspective view showing the test fixture of FIG. 1. In the figure, a part of the test fixture is enlarged and illustrated.

FIG. 4 is an enlarged view showing a part which is enclosed by dotted line A of FIG. 3.

FIG. 5 is a partially cutaway, top view showing the test fixture of FIG. 3. In the figure, a part of the test fixture is enlarged and illustrated.

FIG. 6 is a perspective view showing a main portion which is included in the test fixture of FIG. 1.

FIG. 7 is an enlarged view showing a part which is enclosed by dotted line B of FIG. 6.

FIG. 8 is a top view showing the main portion of FIG. 6. In the figure, a part of the main portion is enlarged and illustrated.

FIG. 9 is a top view showing a printed circuit board and a connector of Patent Document 1. In the figure, the printed circuit board and the connector are in an unmated state where the printed circuit board and the connector are not mated with each other, and hooks are in an opened state.

FIG. 10 is a top view showing the printed circuit board and the connector of FIG. 9. In the figure, the printed circuit board and the connector are in a mated state where the printed circuit board and the connector are mated with each other, and the hooks are in a closed state.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION

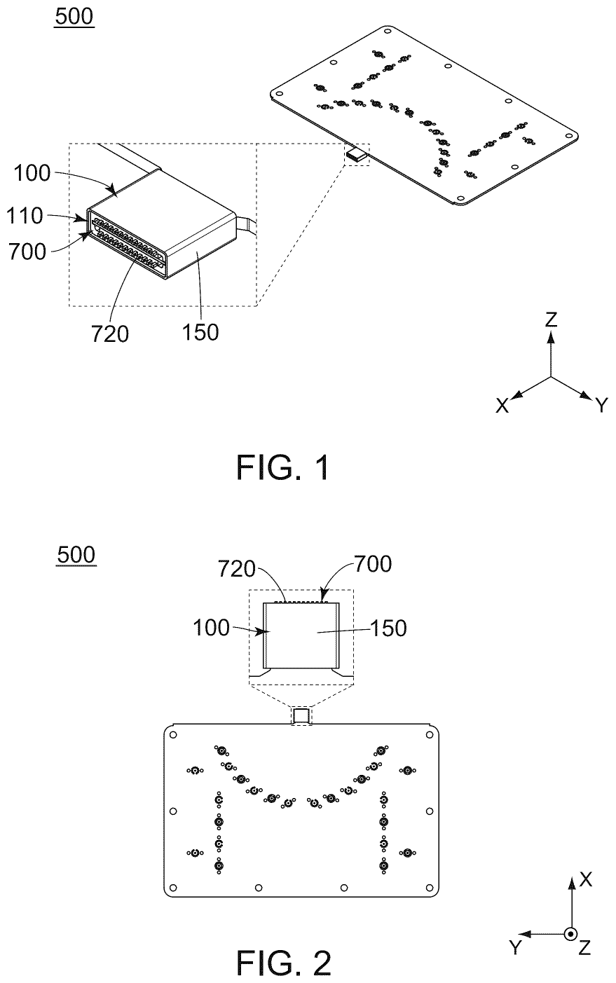

Referring to FIG. 1, a test fixture 500 according to an embodiment of the present invention is used for evaluating transmission characteristics of a mating connector 700.

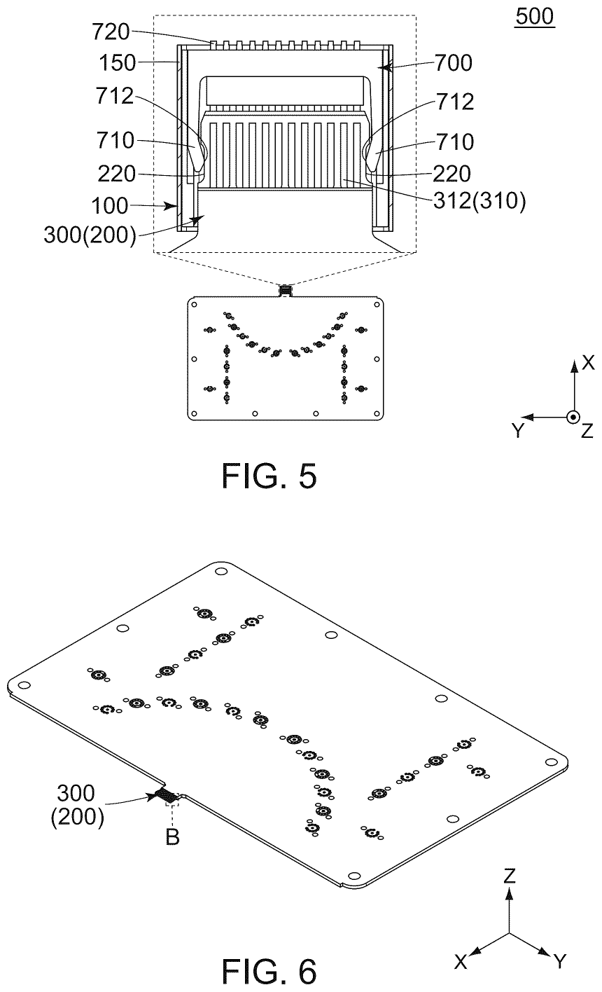

As shown in FIG. 5, the mating connector 700 of the present embodiment comprises two hooks 710 and mating contacts 720.

Referring to FIG. 5, each of the hooks 710 of the present embodiment is made of metal. Each of the hooks 710 extends in a front-rear direction. In the present embodiment, the front-rear direction is an X-direction. Specifically, it is assumed that forward is a positive X-direction while rearward is a negative X-direction. Each of the hooks 710 has resilience. The hooks 710 are positioned away from each other in a lateral direction perpendicular to the front-rear direction. In the present embodiment, the lateral direction is a Y-direction. The two hooks 710 are openable and closable by their own resilience. However, the present invention is not limited thereto. Specifically, the two hooks 710 may be configured to be openable and closable by buttons similar to the hooks 952 of the mating connector 950 of Patent Document 1. Each of the hooks 710 has a lock portion 712. The lock portion 712 faces inward in the lateral direction.

As shown in FIG. 1, the test fixture 500 comprises a connector 100.

As shown in FIG. 1, the connector 100 according to the embodiment of the present invention is mateable with the mating connector 700 in the front-rear direction. The connector 100 has a shell 150 made of metal. The shell 150 is opened at its front end in the front-rear direction. In other words, the connector 100 has an opening portion 110 at its front end in the front-rear direction.

As shown in FIG. 8, the connector 100 of the present embodiment has a main portion 200 which has a tongue-like shape.

As shown in FIG. 5, the main portion 200 of the present embodiment has two opposite side surfaces 220 in the lateral direction. The hooks 710 of the mating connector 700 correspond to the opposite side surfaces 220, respectively, of the main portion 200 in the lateral direction.

Referring to FIG. 8, the main portion 200 has two guide portions 230, two protruding portions 240 and two recessed portions 250.

Referring to FIG. 8, the guide portions 230 of the present embodiment are positioned at opposite ends, respectively, of the main portion 200 in the lateral direction. Each of the guide portions 230 intersects with both the front-rear direction and the lateral direction. More in detail, each of the guide portions 230 is oblique to both the front-rear direction and the lateral direction. Each of the guide portions 230 is positioned at a front end of the main portion 200 in the front-rear direction. The guide portions 230 correspond to the protruding portions 240 and the recessed portions 250, respectively. Each of the guide portions 230 is positioned forward of the corresponding protruding portion 240 in the front-rear direction.

Referring to FIG. 8, the protruding portions 240 of the present embodiment are positioned at the opposite ends, respectively, of the main portion 200 in the lateral direction. Each of the protruding portions 240 protrudes outward in the lateral direction. Each of the protruding portions 240 is positioned between the corresponding guide portion 230 and the corresponding recessed portion 250 in the front-rear direction. Each of the protruding portions 240 is positioned rearward of the corresponding guide portion 230 in the front-rear direction. Each of the protruding portions 240 is positioned forward of the corresponding recessed portion 250 in the front-rear direction.

Referring to FIG. 8, the recessed portions 250 of the present embodiment are positioned at the opposite ends, respectively, of the main portion 200 in the lateral direction. Each of the recessed portions 250 is recessed inward in the lateral direction. Each of the recessed portions 250 is positioned rearward of the corresponding protruding portion 240 in the front-rear direction.

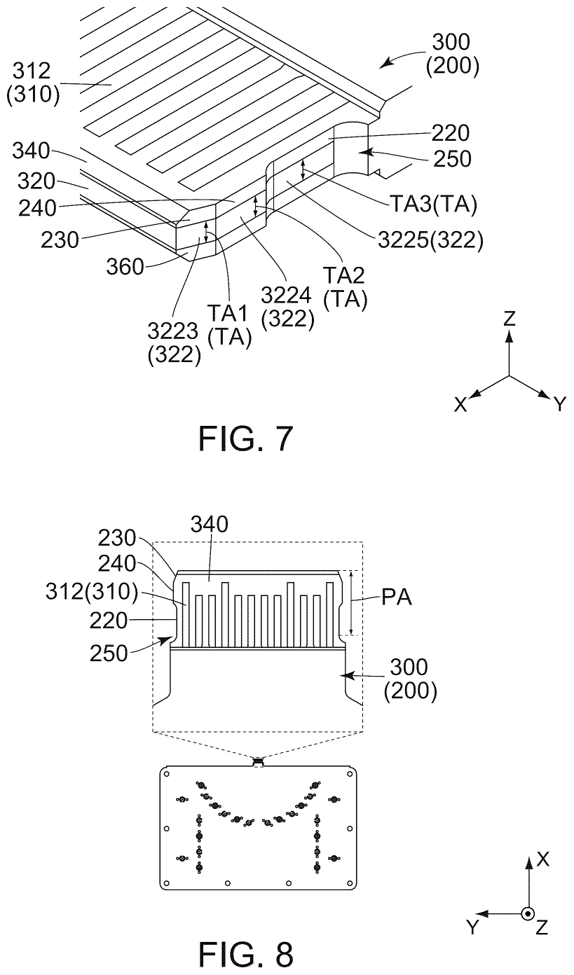

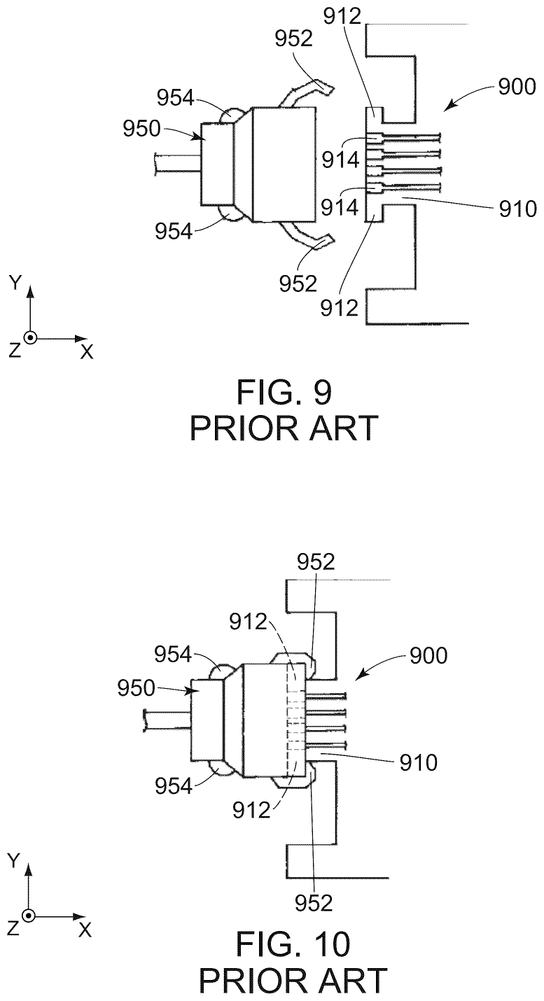

As shown in FIG. 7, the main portion 200 is formed of a multilayer wiring substrate 300. The multilayer wiring substrate 300 includes a first metal conductive layer 310 and a second metal conductive layer 320.

As shown in FIG. 7, the first metal conductive layer 310 of the present embodiment is exposed upward in an up-down direction from the multilayer wiring substrate 300. In the present embodiment, the up-down direction is a Z-direction. Specifically, upward is a positive Z-direction, and downward is a negative Z-direction.

Referring to FIG. 7, the second metal conductive layer 320 of the present embodiment is a ground layer 320. The second metal conductive layer 320 is positioned below the first metal conductive layer 310 in the up-down direction. The second metal conductive layer 320 has two conductive exposed portions 322.

Referring to FIG. 7, the conductive exposed portions 322 are exposed to the outside of the connector 100 at the opposite side surfaces 220, respectively, of the main portion 200. Referring to FIGS. 4 and 5, the conductive exposed portions 322 correspond to the hooks 710, respectively. Referring to FIGS. 4 and 7, a thickness TA of each of the conductive exposed portions 322 is greater than a thickness TB of the lock portion 712 of the corresponding hook 710 of the mating connector 700.

Referring to FIG. 7, the conductive exposed portions 322 correspond to the guide portions 230, the protruding portions 240 and the recessed portions 250, respectively.

As shown in FIG. 7, each of the conductive exposed portions 322 of the present embodiment has a first exposed portion 3223, a second exposed portion 3224 and a third exposed portion 3225.

As shown in FIG. 7, the first exposed portion 3223 of the present embodiment is exposed to the outside of the connector 100 at the corresponding guide portion 230. Referring to FIGS. 4 and 7, a thickness TA1 of the first exposed portion 3223 of each of the conductive exposed portions 322 is greater than the thickness TB of the lock portion 712 of the corresponding hook 710 of the mating connector 700.

As shown in FIG. 7, the second exposed portion 3224 of the present embodiment is exposed to the outside of the connector 100 at the corresponding protruding portion 240. Referring to FIGS. 4 and 7, a thickness TA2 of the second exposed portion 3224 of each of the conductive exposed portions 322 is greater than the thickness TB of the lock portion 712 of the corresponding hook 710 of the mating connector 700.

As shown in FIG. 7, the third exposed portion 3225 of the present embodiment is exposed to the outside of the connector 100 in the corresponding recessed portion 250. Referring to FIGS. 4 and 7, a thickness TA3 of the third exposed portion 3225 of each of the conductive exposed portions 322 is greater than the thickness TB of the lock portion 712 of the corresponding hook 710 of the mating connector 700.

As shown in FIG. 7, the multilayer wiring substrate 300 of the present embodiment further comprises two resin insulating layers 340, 360. The resin insulating layers 340, 360 are positioned at opposite sides, respectively, of the second metal conductive layer 320 in the up-down direction. The resin insulating layer 340 is positioned between the first metal conductive layer 310 and the second metal conductive layer 320 in the up-down direction. Thus, the first metal conductive layer 310 and the second metal conductive layer 320 are insulated from each other.

As shown in FIG. 7, the main portion 200 comprises a plurality of contacts 312.

As shown in FIG. 7, each of the contacts 312 of the present embodiment is formed on the first metal conductive layer 310. Each of the contacts 312 is, at least in part, exposed to the outside of the connector 100. Referring to FIGS. 1 and 7, the contacts 312 are contactable with the mating contacts 720, respectively, in the up-down direction perpendicular to both the front-rear direction and the lateral direction.

Hereinafter, an explanation will be made about contact states between the main portion 200 of the connector 100 and the hook 710 of the mating connector 700 upon the mating of the connector 100 of the test fixture 500 of the present embodiment with the mating connector 700.

First, the mating connector 700 is inserted rearward into the connector 100 of the test fixture 500 through the opening portion 110. Then, a rear end of each of the hooks 710 of the mating connector 700 is brought into contact with the first exposed portion 3223 of the corresponding conductive exposed portion 322 of the connector 100. Meanwhile, the rear end of each of the hooks 710 of the mating connector 700 is in non-contact with any of the resin insulating layers 340, 360 of the connector 100.

From this state, the mating connector 700 is further moved rearward relative to the connector 100. Then, the lock portion 712 of each of the hooks 710 of the mating connector 700 rides on the first exposed portion 3223 of the corresponding conductive exposed portion 322 of the connector 100. As described above, the thickness TA1 of the first exposed portion 3223 of each of the conductive exposed portions 322 is greater than the thickness TB of the lock portion 712 of the corresponding hook 710 of the mating connector 700. Accordingly, the lock portion 712 of each of the hooks 710 of the mating connector 700 is in non-contact with any of the resin insulating layers 340, 360 of the connector 100 in this state.

After that, the mating connector 700 is further moved rearward relative to the connector 100. Then, the lock portion 712 of each of the hooks 710 of the mating connector 700 rides on the second exposed portion 3224 of the corresponding conductive exposed portion 322 of the connector 100. As described above, the thickness TA2 of the second exposed portion 3224 of each of the conductive exposed portions 322 is greater than the thickness TB of the lock portion 712 of the corresponding hook 710 of the mating connector 700. Accordingly, the lock portion 712 of each of the hooks 710 of the mating connector 700 is in non-contact with any of the resin insulating layers 340, 360 of the connector 100 in this state.

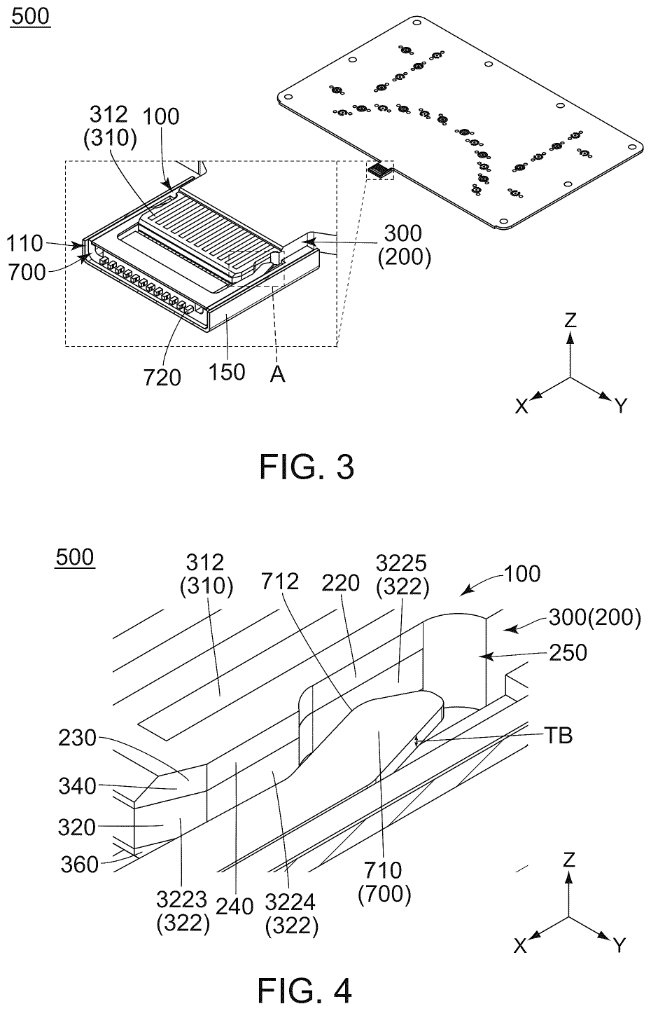

From this state, the mating connector 700 is further moved rearward relative to the connector 100. Then, the connector 100 and the mating connector 700 change their state into a state shown in each of FIGS. 3 and 5. In this state, the contacts 312 of the connector 100 are in contact with the mating contacts 720, respectively, of the mating connector 700. In this state, the lock portion 712 of each of the hooks 710 of the mating connector 700 reaches the inside of the corresponding recessed portion 250 of the connector 100 while the lock portions 712 lock a mated state where the mating connector 700 and the connector 100 are mated with each other. In this state, the lock portion 712 of each of the hooks 710 of the mating connector 700 is in contact with the third exposed portion 3225 of the corresponding conductive exposed portion 322 of the connector 100. That is, the lock portion 712 of each of the hooks 710 is brought into contact with the corresponding conductive exposed portion 322 when the lock portions 712 lock the mated state where the mating connector 700 and the connector 100 are mated with each other. In this state, the lock portion 712 of each of the hooks 710 is electrically connected with the corresponding conductive exposed portion 322. As described above, the second metal conductive layer 320 with the conductive exposed portions 322 is the ground layer 320. Accordingly, the mating connector 700 is grounded to the connector 100. As described above, the thickness TA3 of the third exposed portion 3225 of each of the conductive exposed portions 322 is greater than the thickness TB of the lock portion 712 of the corresponding hook 710 of the mating connector 700. Accordingly, each of the hooks 710 of the mating connector 700 is in non-contact with any of the resin insulating layers 340, 360 of the connector 100 in this state.

As described above, the thickness TA of each of the conductive exposed portions 322 is greater than the thickness TB of the lock portion 712 of the corresponding hook 710 of the mating connector 700, and the lock portion 712 of each of the hooks 710 is brought into contact with the corresponding conductive exposed portion 322 when the lock portions 712 lock the mated state where the mating connector 700 and the connector 100 are mated with each other. Accordingly, as compared to the connector 900 of Patent Document 1, the connector 100 of the present embodiment prevents abrasion of the multilayer wiring substrate 300 of the connector 100 and production of abrasion dust upon the mating of the mating connector 700 with the connector 100. Thus, the connector 100 of the present embodiment avoids reduction of reliability of the electrical connection of the connector 100 and the mating connector 700 by the production of the abrasion dust. Although the hooks 710 of the mating connector 700 of the present embodiment are openable and closable by their own resilience dissimilar to the hooks 952 of the mating connector 950 of Patent Document 1, the test fixture 500 of the present embodiment also exhibits the same advantageous effects as described above when the connector 100 of the present embodiment is mated with a mating connector 700 having hooks 710 that are openable and closable by buttons similar to the hooks 952 of the mating connector 950 of Patent Document 1. That is, regardless of whether the hooks 710 of the mating connector 700 are openable and closable by their own resilience or by buttons, the test fixture 500 of the present embodiment exhibits the same advantageous effects as described above upon the mating of the connector 100 of the present embodiment with the mating connector 700.

Referring to FIGS. 7 and 8, each of the conductive exposed portions 322 extends over an entire length of a predetermined area PA of a corresponding one of the opposite side surfaces 220 in the front-rear direction. Referring to FIGS. 5 and 8, when the mating connector 700 is mated with the connector 100, the lock portion 712 of each of the hooks 710 is slid on the corresponding one of the opposite side surfaces 220 of the main portion 200 over the predetermined area PA. Accordingly, when the mating connector 700, which has the two hooks 710 that are openable and closable by their own resilience, is inserted into and removed from the connector 100 of the test fixture 500, the lock portion 712 of each of the hooks 710 is slid not on the resin insulating layer 340, 360 of the multilayer wiring substrate 300 but only on the corresponding conductive exposed portion 322. Thus, the connector 100 of the present embodiment further prevents the abrasion of the multilayer wiring substrate 300 of the connector 100 and the production of the abrasion dust upon the mating of the connector 100 with the mating connector 700 which has the two hooks 710 that are openable and closable by their own resilience. Consequently, the connector 100 of the present embodiment further avoids the reduction of the reliability of the electrical connection of the connector 100 and the mating connector 700 by the production of the abrasion dust.

Although the specific explanation about the present invention is made above referring to the embodiments, the present invention is not limited thereto and is susceptible to various modifications and alternative forms. In addition, the above embodiments and variations may also be combined.

Although the connector 100 of the test fixture 500 of the present embodiment is configured so that each of the conductive exposed portions 322 extends over the entire length of the predetermined area PA of the corresponding one of the opposite side surfaces 220 in the front-rear direction, the present invention is not limited thereto. Specifically, the connector 100 may be modified so that the conductive exposed portion 322 does not extend over the entire length of the predetermined area PA of the corresponding one of the opposite side surfaces 220 in the front-rear direction. However, if the connector 100 is modified as described above, the modified connector 100 might have a drawback as follows: when the modified connector 100 is mated with a mating connector 700 having two hooks 710 that are openable and closable by their own resilience similar to the mating connector 700 of the present embodiment, a lock portion 712 of the hook 710 of the mating connector 700 is slid on a part, where a conductive exposed portion 322 is not exposed to the outside of the modified connector 100, of the corresponding one of the opposite side surfaces 220 of the modified connector 100 and the part of the corresponding one of the opposite side surfaces 220 is abraded to produce abrasion dust. Accordingly, each of the conductive exposed portions 322 is preferred to be extend over the entire length of the predetermined area PA of the corresponding one of the opposite side surfaces 220 in the front-rear direction similar to those of the connector 100 of the present embodiment.

While there has been described what is believed to be the preferred embodiment of the invention, those skilled in the art will recognize that other and further modifications may be made thereto without departing from the spirit of the invention, and it is intended to claim all such embodiments that fall within the true scope of the invention.

What is claimed is:

1. A connector mateable with a mating connector in a front-rear direction, wherein:
the mating connector comprises two hooks and a mating contact;
the hooks are positioned away from each other in a lateral direction perpendicular to the front-rear direction;
each of the hooks extends in the front-rear direction;
each of the hooks has a lock portion;
the lock portion faces inward in the lateral direction;
the connector has a main portion which has a tongue-like shape;
the main portion has opposite side surfaces in the lateral direction;
the hooks correspond to the opposite side surfaces, respectively, of the main portion;
the main portion is formed of a multilayer wiring substrate;
the multilayer wiring substrate includes a first metal conductive layer and a second metal conductive layer;
the first metal conductive layer and the second metal conductive layer are insulated from each other;
the main portion comprises a plurality of contacts;
each of the contacts is formed on the first metal conductive layer;
each of the contacts is, at least in part, exposed to an outside of the connector;
the contact is contactable with the mating contact in an up-down direction perpendicular to both the front-rear direction and the lateral direction;
the second metal conductive layer has two conductive exposed portions;
the conductive exposed portions are exposed to the outside of the connector at the opposite side surfaces, respectively, of the main portion;
the conductive exposed portions correspond to the hooks, respectively;
each of the conductive exposed portions has a thickness greater than a thickness of the lock portion of the corresponding hook of the mating connector; and
the lock portion of each of the hooks is brought into contact with the corresponding conductive exposed portion when the lock portions lock a mated state where the mating connector and the connector are mated with each other.

2. The connector as recited in claim 1, wherein:
when the mating connector is mated with the connector, the lock portion of each of the hooks is slid on a corresponding one of the opposite side surfaces of the main portion over a predetermined area; and
each of the conductive exposed portions extends over an entire length of the predetermined area of the corresponding one of the opposite side surfaces in the front-rear direction.

3. The connector as recited in claim 1, wherein:
the multilayer wiring substrate further comprises two resin insulating layers;
the second metal conductive layer has opposite sides in the up-down direction; and
the resin insulating layers are positioned at the opposite sides, respectively, of the second metal conductive layer.

4. The connector as recited in claim 1, wherein:
each of the hooks is made of metal;
the second metal conductive layer is a ground layer; and
the lock portion of each of the hooks is electrically connected with the corresponding conductive exposed portion under the mated state.

5. A test fixture for evaluating transmission characteristics of the mating connector, wherein the test fixture comprises the connector as recited in claim 4.
